(19) United States
(12) Patent Application Publication
(10) Pub. No.: US 2026/0050010 A1
(43) Pub. Date: Feb. 19, 2026

(54) PROBE FOR PROBE CARD

(71) Applicant: JAPAN ELECTRONIC MATERIALS CORPORATION, Amagasaki-shi, Hyogo (JP)

(72) Inventor: Tomoyuki TAKEDA, Amagasaki-shi, Hyogo (JP)

(73) Assignee: JAPAN ELECTRONIC MATERIALS CORPORATION, Amagasaki-shi, Hyogo (JP)

(21) Appl. No.: 19/102,033

(22) PCT Filed: Sep. 21, 2022
(86) PCT No.: PCT/JP2022/035189

§ 371 Date: Feb. 7, 2025

(51) Int. Cl. G01R 1/073; G01R 1/067

(52) U.S. Cl. CPC G01R 1/07357; G01R 1/06733; G01R 1/06761; G01R 1/07342

(57) ABSTRACT

A probe for a probe card, which is to be placed in contact with electrode pads of a semiconductor device and used for supply of power, input/output of signals, and grounding when performing an operation test of individual semiconductor devices formed on a wafer, includes a plurality of three-dimensionally shaped and enclosed stress-distributing chambers which are embedded inside the probe and have vertices and ridges formed by inner wall surfaces.

### TECHNICAL FIELD

The present disclosure relates to a probe for a probe card.

### BACKGROUND ART

A probe card is an electrical connection device used to perform operation tests on individual semiconductor devices formed on a wafer. It achieves the tests by bringing probes into contact with the electrode pads of the semiconductor devices to supply power, enable signal input/output, and provide grounding.

The probes are arranged on the surface of the probe card and are configured such that their tips are pressed against the electrode pads of semiconductor devices with a predetermined pressing force.

In order to increase the number of semiconductor devices formed on a wafer, it is necessary to reduce the size of the semiconductor devices. Therefore, the electrode pads of the semiconductor devices are designed to be smaller, and the pitch between the electrode pads is also reduced.

To accommodate the miniaturization of semiconductor devices, it is necessary to miniaturize the probes. However, miniaturizing the probes causes a problem in that their mechanical strength is diminished.

To ensure reliable electrical and mechanical contact with the electrode pads of semiconductor devices, for instance, Patent Document 1 proposes a structure employing multilayered metal sheets in a probe.

### CITATION LIST

### Patent Document

Patent Document 1: Japanese Laid-Open Patent Publication No. 2018-501490

### SUMMARY OF THE INVENTION

### Problem to be Solved by the Invention

Patent Document 1 discloses a probe that includes at least one multilayer structure comprising the superposition of a core and a first inner coating layer, and an outer coating layer made of a material harder than the core, which completely covers this multilayer structure.

As shown in Patent Document 1, to achieve favorable electrical and mechanical contact, a configuration in which a plurality of layers of different materials are superposed is preferred. However, there is a limit to meeting the demand for reducing the thickness of the cross-section of the probe, and a further breakthrough was required.

In the inspection process using a probe card, after the probe makes contact with the electrode pads of a semiconductor device, the probe card is further moved closer to the semiconductor wafer (overdrive) to press the probe against the electrode pads of the semiconductor device.

For this reason, the probe is required to possess mechanical strength sufficient to avoid destruction, even when a contact pressure exceeding a predetermined value is applied. To prevent damage to the probe, it is essential to ensure that localized stress concentrations do not occur within the probe. To achieve this, probes with a surface that is as smooth as possible and free of scratches have been sought.

However, there is a limit to how much metal surfaces can be smoothed, and the thinner the cross-sectional thickness of a probe, the more prone it becomes to deformation under external forces (i.e., Mechanical strength decreases).

Present disclosure has been made to solve the aforementioned problems and provides a probe for a probe card that, even when miniaturized, ensures reliable contact with the electrode pads of semiconductor devices with adequate contact force and possesses sufficient strength to resist destruction even when a contact pressure exceeding a predetermined value is applied.

Specifically, the probe for a probe card disclosed in this disclosure is designed not to prevent stress concentration but rather to intentionally disperse the locations where stress concentration occurs. This structural approach allows the probe to withstand high stress and offers a probe for a probe card with enhanced mechanical strength.

### Means to Solve the Problem

A probe for a probe card according to the present disclosure includes: a plurality of three-dimensional enclosed stress dispersion chambers embedded inside the probe, each chamber having ridges and vertices formed by inner wall surfaces.

### Effect of the Invention

According to the probe for a probe card disclosed in this disclosure, even if the probe's thickness is reduced, a probe for a probe card with high mechanical strength can be provided by effectively dispersing the points of stress concentration.

### BRIEF DESCRIPTION OF THE DRAWINGS

FIG. 1 is a schematic diagram illustrating the state of inspecting an electronic circuit using the probe card according to Embodiment 1.

FIG. 2 is a perspective view of the probe according to Embodiment 1.

FIG. 3 is a plan view showing the shapes of the three metallic layers composing the probe according to Embodiment 1.

FIG. 4 is a cross-sectional view along line A-A of FIG. 2, showing a section perpendicular to the longitudinal direction Z of the probe.

FIG. 5 is a perspective view of the probe according to Embodiment 2.

FIG. 6 is a plan view showing the shapes of the three metallic layers composing the probe according to Embodiment 2.

FIG. 7 is a cross-sectional view along line B-B of FIG. 5.

FIG. 8 is a cross-sectional view of the probe according to Embodiment 3, cut perpendicularly to the longitudinal direction Z thereof.

FIG. 9 is a perspective view of the probe according to Embodiment 4.

FIG. 10 is a plan view showing the shapes of the three metallic layers composing the probe according to Embodiment 4.

FIG. 11 is a perspective view of the probe according to Embodiment 5.

FIG. 12A is a cross-sectional view along line C-C of FIG. 11.

FIG. 12B is a cross-sectional view illustrating a modified example of the probe according to Embodiment 5.

### DESCRIPTION OF EMBODIMENTS

### Embodiment 1

A probe for a probe card according to Embodiment 1 will be described below with reference to the drawings.

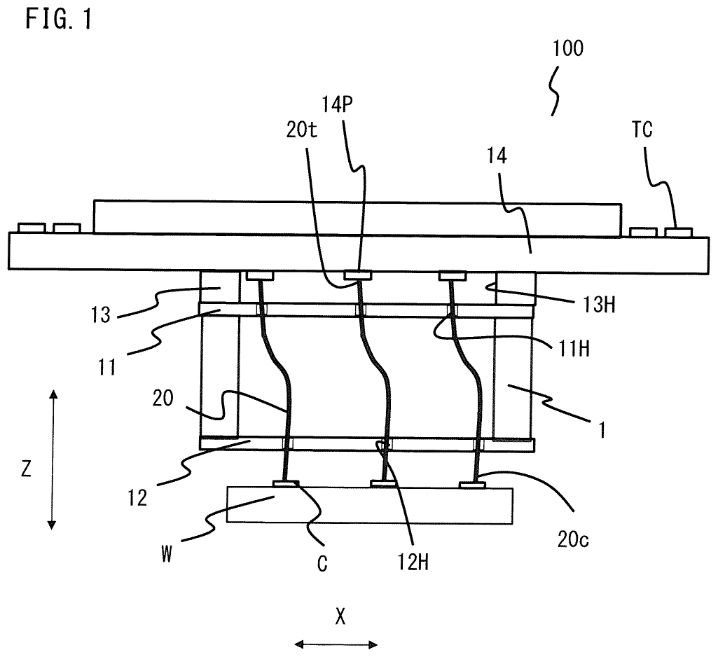

FIG. 1 schematically illustrates the state of inspecting an electronic circuit using the probe card 100.

In this specification, the upper side of FIG. 1 is referred to as “upper,” and the lower side is referred to as “lower.” That is, from the perspective of the probe card 100, the inspection target side is referred to as “lower.” Additionally, the left and right direction in FIG. 1 is referred to as the buckling direction X, while the direction extending from the front to the back of the plane of the figure (and vice versa) is referred to as the direction Y orthogonal to the buckling direction X. The longitudinal direction of the probe 20 (the vertical direction in FIG. 1) is referred to as the longitudinal direction Z.

The probe card 100 is a device used to inspect the electrical characteristics of electronic circuits formed on a semiconductor wafer W. The probe card 100 is includes a large number of probes 20, each of which makes contact with an electrode C on the electronic circuit. The characteristic inspection of the electronic circuit is performed by moving the semiconductor wafer W closer to the probe card 100 to bring the tips of the probe 20 into contact with the electrodes C on the electronic circuit and connecting a tester device (not shown) via the tester connection electrodes TC of the wiring board 14 of the probe card 100 and the probe 20.

The probe card 100 includes a hollow frame 1, an upper guide 11 attached to the upper end of the frame 1, a lower guide 12 attached to the lower end of the frame 1, a fixing plate 13 fixing the upper guide 11, and a wiring board 14. An intermediate guide may also be provided between the upper guide 11 and the lower guide 12.

The upper guide 11 has a plurality of guide holes 11H penetrating in the up-down direction. The lower guide 12, provided below the upper guide 11, also has a plurality of guide holes 12H penetrating in the up-down direction. The upper part of the group of guide holes 11H in the upper guide 11 corresponds to an opening 13H formed in the fixing plate 13. The wiring board 14 has, on a lower surface thereof, a plurality of probe connection pads 14P contacting with the upper ends of the probes 20.

A plurality of probes 20 are guided by being inserted through the guide holes 12H and the guide holes 11H. The probes 20 are vertically-type probes positioned perpendicular to the inspection target (the electronic circuit formed on the semiconductor wafer W).

The left and right direction in FIG. 1 corresponds to the buckling direction X of the probes 20, which is the direction in which the probes 20 elastically bend or buckle during the overdrive of the probe card 100. The probes 20 has an elongated rectangular pillars shape and extending vertically in a straight line. Each probe 20 has a contact portion 20c at a lower end (one end) thereof and a terminal portion 20t at an upper end (the other end) thereof.

During overdrive, the probes 20 are subjected to compressive forces along their longitudinal direction Z, causing them to buckle in the buckling direction X in response to the reaction force from the inspection target. The contact portion 20c retracts toward the terminal portion 20t side, generating stress within the probe 20 during this process.

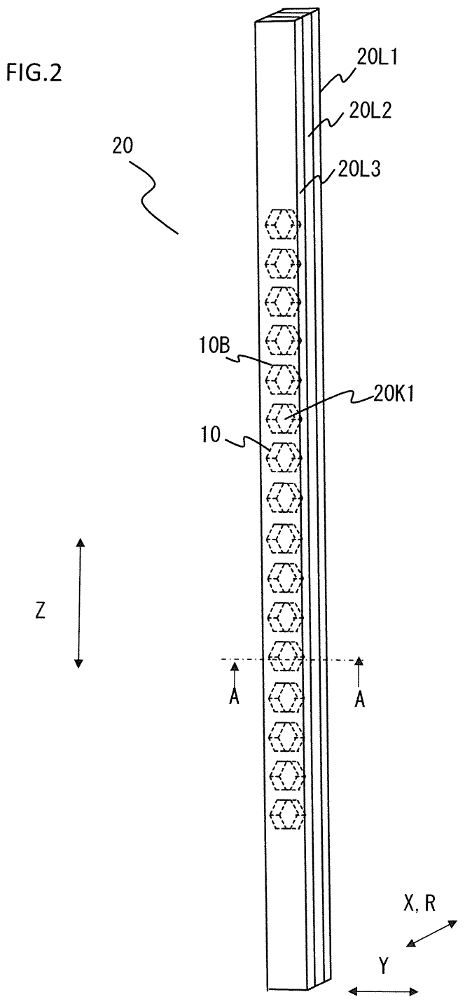

FIG. 2 is a perspective view of the probe 20.

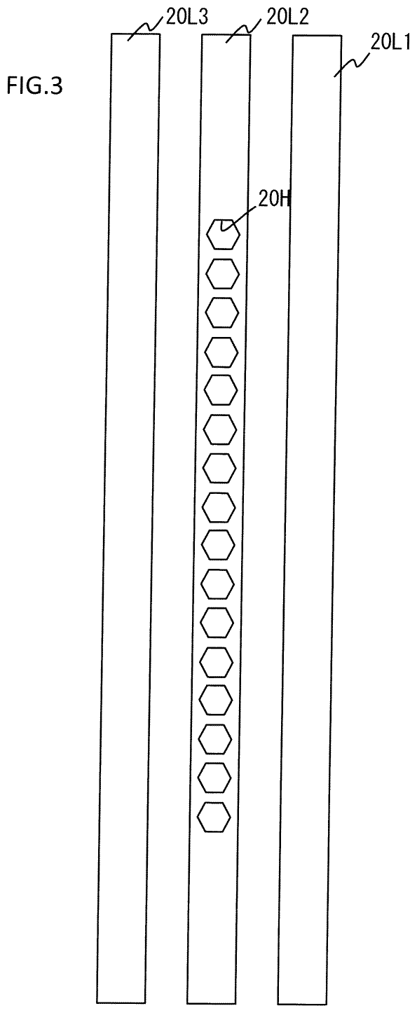

FIG. 3 is a plan view showing the shapes of the three metallic layers constituting the probe 20.

The probe 20 is composed of conductive metal. The first metallic layer 20L1, second metallic layer 20L2, and third metallic layer 20L3 are thin layers of the same metal. The first metallic layer 20L1 and the third metallic layer 20L3 are formed as flat plates. The second metallic layer 20L2, sandwiched between the first metallic layer 20L1 and third metallic layer 20L3, includes a plurality of hexagonal prism-shaped holes 20H spaced along the longitudinal direction Z of the probe 20. These holes 20H penetrate the second metallic layer 20L2 in the stacking direction R of the metallic layers of the probe 20. The first metallic layer 20L1, the second metallic layer 20L2, and the third metallic layer 20L3 are integrated by sequentially stacking and welding them together.

In FIG. 2, the buckling direction X is aligned with the stacking direction R of the three metallic layers. However, the buckling direction may alternatively be set as the direction Y, which is perpendicular to the stacking direction R of the metallic layers.

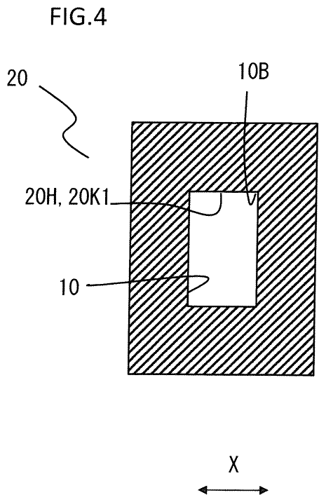

FIG. 4 is a sectional view taken along line A-A of FIG. 2, showing a cross-section of the probe 20 perpendicular to longitudinal direction Z thereof. In FIG. 4, the left-right direction corresponds to the buckling direction X. The cross-section perpendicular to the longitudinal direction Z of the probe 20, at locations where holes 20H are present in the second metallic layer 20L2, appears as shown in FIG. 4. Each hole 20H forms a hollow cavity 20K1 (stress dispersion chamber), which is enclosed by inner walls thereof and the first metallic layer 2011 and the third metallic layer 2013. These cavities 20K1 are thus formed inside the probe 20.

When comparing a probe A without the cavities 20K1 to a probe 20 with the cavities 20K1, the relationship between the overdrive amount and the contact force indicates that the probe 20 with the cavities 20K1 achieves a lower contact force.

Furthermore, the effects of the cavity 20K1 were analyzed. Using finite element method (FEM) analysis, the maximum stress of the probes was determined for probe A without the cavity 20K1 and probe 20 with hexagonal prism-shaped cavities 20K1. The results revealed that when external force is applied, the stress concentrates at the vertices 10B and ridges 10 formed by the adjacent surfaces of the cavity 20K1, as shown in FIG. 2.

Therefore, by embedding hexagonal prism-shaped cavities 20K1 as stress dispersion chambers at predetermined intervals along the longitudinal direction Z of the probe 20, the stress can be evenly dispersed across the vertices 10B and ridges 10, enhancing the mechanical strength of the probe.

The first metallic layer 20L1, second metallic layer 20L2, and third metallic layer 20L3 of the probe 20 are manufactured using so-called Micro Electro Mechanical Systems (MEMS) technology. MEMS technology employs photolithography and sacrificial layer etching techniques to create fine three-dimensional structures. Photolithography is a micro-patterning technique using photoresist, commonly employed in semiconductor manufacturing processes. Sacrificial layer etching involves forming a sacrificial layer underneath, constructing structural layers thereon, and subsequently removing only the sacrificial layer by etching to create three-dimensional structures.

In processing for forming the first metallic layer 20L1 to the third metallic layer 20L3, known plating technology may be used. For example, by immersing a substrate as a cathode and a metal piece as an anode in an electrolyte solution and applying voltage between the electrodes, metal ions in the electrolyte can adhere to the substrate's surface. This process is known as electroplating, a wet process that requires drying after plating to obtain the respective the first metallic layer 20L1 to the third metallic layer 20L3. After drying, the first metallic layers 20L1 to the third metallic layer 20L3 are stacked and welded together. The contact portion 20c is then formed through polishing (polishing step).

According to the probe for a probe card disclosed in Embodiment 1, the stress generated inside the probe 20 during inspection is dispersed to the vertices 10B and ridges 10 of the cavities 20K1, enabling both the maintenance of mechanical strength and the reduction of contact force.

### Embodiment 2

A probe for a probe card according to Embodiment 2 will be described below, with an emphasis on the differences from Embodiment 1.

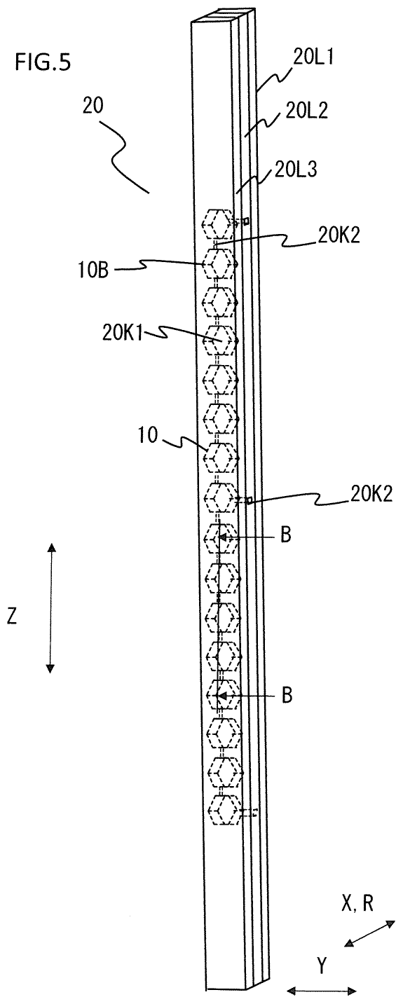

FIG. 5 is a perspective view of the probe 20.

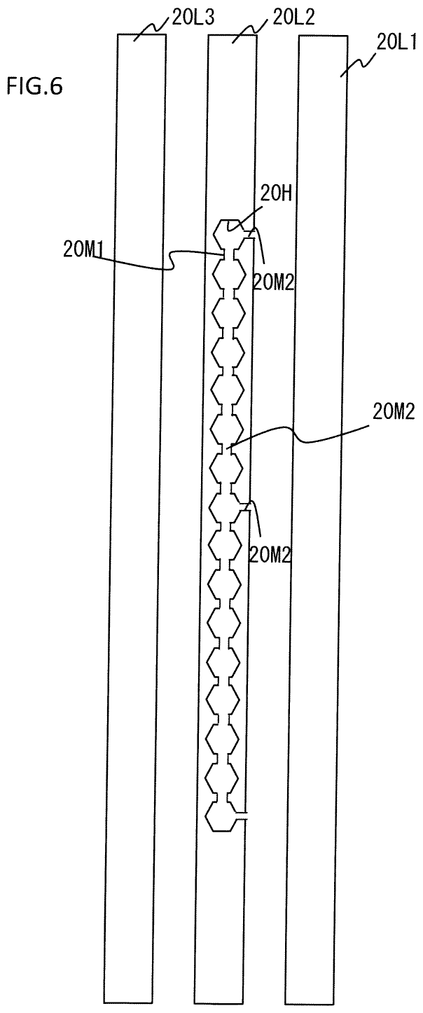

FIG. 6 is a plan view showing the shapes of the three metallic layers constituting the probe 20.

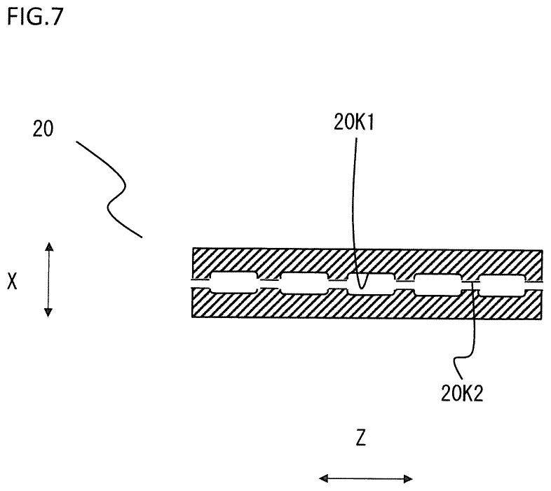

FIG. 7 is a sectional view taken along line B-B of FIG. 5.

In Embodiment 1, the probe 20 was described as having a plurality of independent hexagonal prism-shaped cavities 20K1 arranged and embedded along the longitudinal direction Z inside a metallic pillar consisting of three metallic layers. In Embodiment 2, a plurality of cavities 20K1 of the probe 20 are interconnected by narrow cavities 20K2. Additionally, the cavities 20K2 communicate with the outside of the probe 20 at several locations.

The cavities 20K1 and cavities 20K2 are initially formed as sacrificial layers during the manufacturing process of a probe 20 and are formed by removing the sacrificial layers through etching. That is, in Embodiment 1, to form the cavities 20K1, the first metallic layer 2011 to the third metallic layer 20L3 needed to be manufactured individually and then welded together. In Embodiment 2, all the holes 20H in the second metallic layer 20L2 are connected by grooves 20M1. Furthermore, by forming at least two grooves 20M2 that connect some holes 20H to the outside of the probe 20 and open to the outside, the probe 20 can be manufactured through a unified process.

The manufacturing process of the probe 20 proceeds roughly as described below. First, the first metallic layer 2011 is formed. Next, parts of the second metallic layer 20L2 other than the holes 20H and the grooves 20M1 and 20M2 are formed. Then, sacrificial layers are formed inside the holes 20H and the grooves 20M1 and the grooves 20M2. Next, the third metallic layer 2013 is formed. Finally, the sacrificial layers are removed by dissolving, forming a plurality of cavities 20K1 and cavities 20K2 inside the probe 20.

According to the probe for a probe card disclosed in Embodiment 2, all processes can be completed as a single continuous MEMS process. Therefore, in addition to the effects of Embodiment 1, it is possible to provide a probe 20 with enhanced mechanical strength compared to Embodiment 1.

### Embodiment 3

A probe for a probe card according to Embodiment 3 will be described below, focusing on the parts that differ from Embodiment 1.

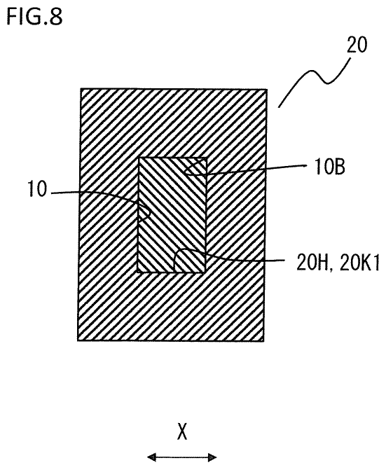

FIG. 8 is a cross-sectional view of the probe 20 cut perpendicular to longitudinal direction Z thereof.

In this embodiment, an example is explained in which the cavity 20K1 is sealed with a material different from the probe 20 body. As shown in FIG. 4, the cavity 20K1 described in Embodiment 1 contains a material softer than the surrounding probe 20 body. Examples of the material include metals such as Au or resin. In the case of filling with Au, a layer of Au is formed in the cavities 20K1 after forming the second metallic layer 20L2 described in Embodiment 2, and then the third metallic layer 20L3 is formed and seals the cavities 20K1. The same process applies to resin.

According to the probe for a probe card disclosed in Embodiment 3, as in Embodiment 2, all processes can be completed as a single unified process using MEMS. Therefore, in addition to the effects of Embodiment 1, a probe 20 with enhanced mechanical strength can be provided.

Additionally, when Au or similar metals are used as the material contained in the holes 20H, the conductivity of a probe is improved while achieving the same effects as in Embodiment 1. When resin is used, the flexibility of the probe 20 during buckling deformation can be enhanced.

### Embodiment 4

A probe for a probe card according to Embodiment 4 will be described below, with a focus on the differences from Embodiment 1.

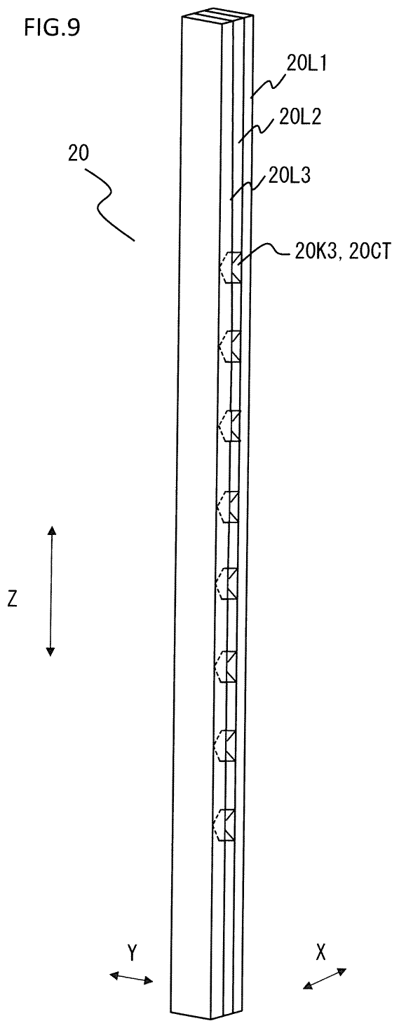

FIG. 9 is a perspective view of the probe 20.

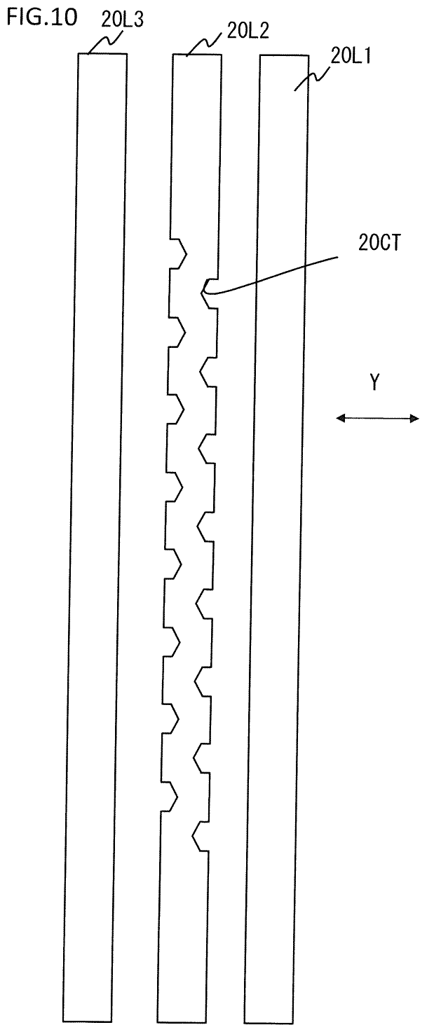

FIG. 10 is a plan view showing the shapes of the three metallic layers constituting the probe 20.

The probe 20 is formed of three metallic layers, as in Embodiment 1. The difference between the probe 20 of this embodiment and that of Embodiment 1 lies in the configuration of the second metallic layer 20L2. On both sides of the second metallic layer 20L2 in the direction Y perpendicular to the buckling direction X, recessed cutout portions 20CT, which are indented toward the inside of the probe 20, are alternately arranged and provided along the longitudinal direction Z of the probe 20.

The manufacturing process of the probe 20 is roughly as follows. First, the first metallic layer 20L1 is formed. Next, parts of the second metallic layer 20L2 other than the portions that will become the cutout portions 20CT are formed on the first metallic layer 20L1. Then, sacrificial layers are formed in the cutout portions 20CT. Next, the third metallic layer 20L3 is formed on top of the second metallic layer 2012. Finally, the sacrificial layers are dissolved to form a plurality of cavities 20K3 inside the probe 20. These cavities 20K3 are open to the outside of the probe 20.

Similar to Embodiment 3, the cavities 20K3 may optionally be sealed by filling them with resin or a metal softer and electrically lower in resistance than the probe 20 body. In this case, the same beneficial effects as Embodiment 3 can be obtained.

### Embodiment 5

A probe for a probe card according to Embodiment 5 will be described below, focusing on the parts that differ from Embodiment 1.

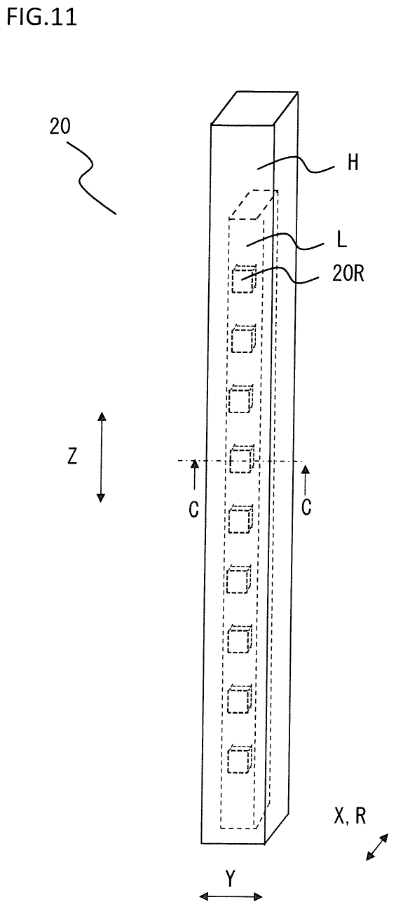

FIG. 11 is a perspective view of the probe 20.

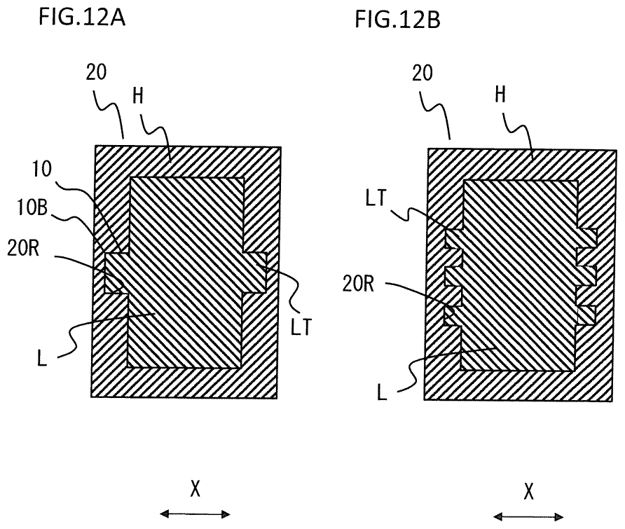

FIG. 12A is a sectional view taken along line C-C of FIG. 11.

FIG. 12B is a sectional view showing a modification of the probe 20.

As shown in FIG. 11, the probe 20 is made of two distinct types of metals with different electrical resistivities. One is the inner metal constituting the low-resistance portion L, which is made of low-resistivity metals such as copper (Cu), gold (Au), or silver (Ag). The low-resistance portion L serves to improve conductivity and enhance current-carrying performance. The other is the outer metal constituting the high-resistance portion H, which is made of metals with higher resistivity and lower conductivity than the low-resistance portion L, such as palladium-cobalt (PdCo) alloy. The high-resistance portion H has high mechanical strength and spring properties and serves to ensure and maintain the mechanical strength of the probe 20.

As shown in FIGS. 12A and 12B, the high-resistance portion H of the probe 20 surrounds the low-resistance portion L. When focusing only on the high-resistance portion H, a plurality of rectangular prism-shaped recesses 20R are formed on the inner walls of both sides in the buckling direction X. These recesses 20R (stress dispersion chambers) are formed at uniform intervals along the longitudinal direction Z of the probe 20.

As shown in FIG. 12B, a plurality of rows of small recesses 20R may optionally be arranged along the longitudinal direction Z of the probe 20. The inside of each recess 20R is the low-resistance portion L. Therefore, when focusing only on the low-resistance portion L, it includes a plurality of protrusions LT that extend in the buckling direction X from both surfaces in the buckling direction X. As described above, stress acting inside the probe 20 concentrates at each vertex 10B and ridge 10 formed in the probe 20. Thus, by providing a plurality of recesses 20R uniformly and evenly inside the high-resistance portion H, which has high mechanical strength and spring properties, it is possible to achieve uniform dispersion of the stress acting inside the probe 20 during buckling deformation.

Although the disclosure is described above in terms of various exemplary embodiments and implementations, it should be understood that the various features, aspects, and functionality described in one or more of the individual embodiments are not limited in their applicability to the particular embodiment with which they are described, but they can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

100 probe card
1 frame
10 ridge
10B vertex
11 upper guide
11H guide hole
12 lower guide
12H guide hole
13 fixing plate
13H opening
14 wiring board
14P probe connection pad
20 probe
20c contact portion
20H hole
20K1, 20K2, 20K3 cavity
20M1, 20M2 groove
20R indentation
20t terminal portion
C electrode
H high-resistance portion
20CT recessed portion
L low-resistance portion
H high-resistance portion
20L1 first metallic layer
20L2 second metallic layer
20L3 third metallic layer
LT protrusion
R stacking direction
TC tester connection electrode
W semiconductor wafer
X buckling direction
Y direction orthogonal to buckling direction x
Z longitudinal direction

1. A probe for a probe card, wherein the probe includes a plurality of three-dimensional enclosed stress dispersion chambers embedded inside the probe, each chamber having ridges and vertices formed by inner wall surfaces.

2. (canceled)

3. A probe for a probe comprising:
a low-resistance portion made of a metallic layer with low electrical resistance; and
a high-resistance portion, located outside of the low-resistance portion, which has higher electrical resistance than the low-resistance portion and possesses spring properties, wherein
the probe includes a plurality of three-dimensional stress dispersion chambers embedded inside the probe, each chamber having ridges and vertices formed by inner wall surfaces,
the stress dispersion chambers are formed in the high-resistance portion.

4. The probe for a probe card according to claim 3, wherein
the stress dispersion chambers are open to the outer surface of the probe.

5. The probe for a probe card according to claim 3 wherein
the stress dispersion chambers contain metal that is electrically lower in resistance than the surrounding metal.

6. The probe for a probe card according to claim 3, wherein
the stress dispersion chambers contain resin.

7. The probe for a probe card according to claim 3, wherein
the stress dispersion chambers contain the same metal as the low-resistance portion.

8. (canceled)

9. A probe for a probe card, wherein
the probe includes a plurality of three-dimensional stress dispersion chambers embedded inside the probe, each chamber having ridges and vertices formed by inner wall surfaces, the stress dispersion chambers are hollow and all the stress dispersion chambers communicate with the outside of the probe.
